(19) United States
(12) Patent Application Publication
(10) Pub. No.: US 2021/0226137 A1
(43) Pub. Date: Jul. 22, 2021

(54) ARRAY SUBSTRATE AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Yu ZHAO, Wuhan (CN)

(21) Appl. No.: 16/094,478

(22) PCT Filed: Aug. 13, 2018
(86) PCT No.: PCT/CN2018/100230

§ 371 Date: Oct. 18, 2018

(30) Foreign Application Priority Data
Jun. 29, 2018 (CN) 201810700457.1

(51) Int. Cl. H01L 51/00; H01L 27/32; H01L 51/56

(52) U.S. Cl. CPC H01L 51/0097; H01L 27/3258; H01L 27/1218; H01L 51/56; H01L 27/3262

(57) ABSTRACT

An array substrate, a display panel having the array substrate, a method of manufacturing the display panel, a display, and an electronic device having the same are provided. In the disclosure, a first contact hole and a second contact hole are formed by a photomask, thereby omitting the number of the photomasks in a process and simplifying the process. In addition, in the disclosure, all portions of the inorganic insulating layer (including a buffer layer, a first gate insulating layer, a second gate insulating layer, and a interlayer insulating layer) in the array substrate that do not function as insulation are removed from the inorganic insulating layer, thereby effectively preventing inorganic materials from being broken when the display panel is folded.

### FIELD OF INVENTION

This disclosure relates to display technology, and more particularly to an array substrate, display panel, a method of manufacturing the array substrate, and a display and an electronic device having the same.

### BACKGROUND OF INVENTION

In recent years, organic light-emitting diode (OLED) display panels have become very popular display devices, because OLED display devices have self-luminosity, wide viewing angles, fast response times, high luminous efficiency, wide color gamut, low energy consumption, are thinner, for application in large size and flexible panels, have a simple process, and have a low cost potential.

In conventional flexible OLEDs, an inorganic insulating layer (for example, a first gate insulating layer, a second gate insulating layer, and a interlayer insulating layer) generally covers a flexible substrate completely, and thus inorganic materials are easily broken when the display panel is folded. It causes the OLEDs to malfunction.

Therefore, it is necessary to provide a new array substrate and a display panel to which the array substrate is applied, a method of manufacturing the display panel, a display, and an electronic device to solve above drawbacks.

### SUMMARY OF INVENTION

The object of this disclosure is to provide an array substrate. In this disclosure, all portions of a inorganic insulating layer (including a buffer layer, a first gate insulating layer, a second gate insulating layer, and a interlayer insulating layer) in the array substrate that do not function as insulation are removed from the inorganic insulating layer and only necessary portions for insulation are retained, thereby effectively preventing inorganic materials from being broken when a display panel having the array substrate is folded. Thus, a flexibility of the display panel is increased.

In order to solve the above-mentioned drawbacks, the technical solutions provided by the disclosure are as follows.

This disclosure provides an array substrate comprising a first region and a second region. The array substrate comprises a flexible substrate, a first layer disposed on the flexible substrate and located on the first region, a second layer disposed on the flexible substrate and located on the first region, and an inorganic insulating layer disposed between the first layer and the second layer and located on the first region and not located on the second region. One of the first layer and the second layer is a metal layer. The first layer comprises an active layer. The second layer comprises a first gate. The inorganic insulating layer comprises a first gate insulating layer disposed on the active layer and the first gate.

In an embodiment of the disclosure, the first layer further comprises a second gate, and the inorganic insulating layer further comprises a second gate insulating layer disposed between the first gate and the second gate.

In an embodiment of the disclosure, the array substrate further comprises an organic dielectric layer, the organic dielectric layer comprises a first portion disposed on the second region and a second portion disposed on the inorganic insulating layer.

In an embodiment of the disclosure, the second layer further comprises a source/drain, the source/drain extends through the first gate insulating layer and the second gate insulating layer and connects with the active layer, and the inorganic insulating layer further comprises an interlayer insulating layer disposed between the second gate and the source/drain, the second portion of the organic dielectric layer is disposed between the source/drain and the interlayer insulating layer.

In an embodiment of the disclosure, the second region comprises a curved portion corresponding to a non-display area of a display panel, and the first region comprises a functional portion corresponding to a display area of the display panel and adjacent to the curved portion, the array substrate is provided with a groove adjacent to an interface between the curved portion and the display portion, and the groove penetrates through the organic dielectric layer to expose the first gate insulating layer, the second gate insulating layer and the interlayer insulating layer.

In an embodiment of the disclosure, the array substrate further comprises a buffer layer between the flexible substrate and the active layer, and the source/drain extends through the active layer and the buffer layer.

In an embodiment of the disclosure, the array substrate comprises a functional region corresponding to the display area of the display panel, and the functional region comprises the first region and the second region.

This disclosure further provides an array substrate, comprising a first region and a second region. The array substrate comprises a flexible substrate, a first layer disposed on the flexible substrate and located on the first region, a second layer disposed on the flexible substrate and located on the first region, and an inorganic insulating layer disposed between the first layer and the second layer. The inorganic insulating layer is located on the first region and is not located on the second region.

In an embodiment of the disclosure, the array substrate further comprises an organic dielectric layer, the organic dielectric layer comprises a first portion disposed on the second region.

In an embodiment of the disclosure, the organic dielectric layer further comprises a second portion disposed on the inorganic insulating layer.

In an embodiment of the disclosure, one of the first layer and the second layer is a metal layer.

In an embodiment of the disclosure, the first layer comprises an active layer, the second layer comprises a first gate, and the inorganic insulating layer comprises a first gate insulating layer disposed on the active layer and the first gate.

In an embodiment of the disclosure, the first layer further comprises a second gate, and the inorganic insulating layer further comprises a second gate insulating layer disposed between the first gate and the second gate.

In an embodiment of the disclosure, the second layer further comprises a source/drain, the source/drain extends through the first gate insulating layer and the second gate insulating layer and connects with to the active layer, and wherein the inorganic insulating layer further comprises an interlayer insulating layer disposed between the second gate and the source/drain, the second portion of the organic dielectric layer is disposed between the source/drain and the interlayer insulating layer.

In an embodiment of the disclosure, the second region comprises a curved portion corresponding to a non-display area of a display panel, and the first region comprises a functional portion corresponding to a display area of the display panel and adjacent to the curved portion, the array substrate is provided with a groove adjacent to an interface between the curved portion and the display portion, and the groove penetrates through the organic dielectric layer to expose the first gate insulating layer, the second gate insulating layer and the interlayer insulating layer.

In an embodiment of the disclosure, the array substrate further comprises a buffer layer between the flexible substrate and the active layer, and the source/drain extends through the active layer and the buffer layer.

In an embodiment of the disclosure, the array substrate comprises a functional region corresponding to the display area of the display panel, and the functional region comprising the first region and the second region.

This disclosure further provides a method of manufacturing a display panel. The display panel comprises an array substrate. The array substrate comprises a first region and a second region. The method comprises steps of:

a step S1 of providing a flexible substrate and a first layer disposed on the flexible substrate, wherein the first layer is located on the first region; and providing a second layer disposed on the flexible substrate, wherein the second layer is located on the first region;

a step S2 of forming an active layer on the flexible substrate;

a step S3 of forming a first gate insulating layer on the active layer, wherein the first gate insulating layer is located on the first region and is not located on the second region;

a step S4 of forming a first gate on the first gate insulating layer, wherein the first gate is located on the first region;

a step S5 of forming a second gate insulating layer on the first gate, wherein the second gate insulating layer is located on the first region and is not located on the second region;

a step S6 of forming a second gate on the first gate insulating layer, wherein the second gate is located on the first region;

a step S7 of forming an interlayer insulating layer on the second gate, wherein the interlayer insulating layer is located on the first region and is not located on the second region;

a step S8 of forming an organic dielectric layer on the interlayer insulating layer, wherein the organic dielectric layer comprises a first portion disposed on the second region and a second portion disposed on the inorganic insulating layer;

a step S9 of forming a source/drain on the interlayer insulating layer, wherein the source/drain extends through the first gate insulating layer and the second gate insulating layer and connects with the active layer, and the inorganic insulating layer further comprises an interlayer insulating layer disposed between the second gate and the source/drain, the second portion of the organic dielectric layer is disposed between the source/drain and the interlayer insulating layer.

The second region comprises a curved portion corresponding to a non-display area of a display panel, and the first region comprises a functional portion corresponding to a display area of the display panel and adjacent to the curved portion, the array substrate is provided with a groove adjacent to an interface between the curved portion and the display portion, and the groove penetrates through the organic dielectric layer to expose the first gate insulating layer, the second gate insulating layer and the interlayer insulating layer.

This disclosure further provides a display panel. The display panel comprises a first region and a second region. The display panel comprises a flexible substrate, a first layer disposed on the flexible substrate and located on the first region, a second layer disposed on the flexible substrate and located on the first region, and an inorganic insulating layer disposed between the first layer and the second layer. The inorganic insulating layer is located on the first region and is not located on the second region.

This disclosure further provides a display panel. The display panel comprises the array substrate described above, or the display panel comprises an array substrate manufactured by the above-mentioned manufacturing method. The display panel includes, but is not limited to, an OLED, a QLED, an LED, a Micro LED, and the like. For convenience of explanation, the OLED is taken as an example for detailed description in the disclosure. It should be understood by those skilled in the art that when the array substrate described in the disclosure is applied to other types display panels (for example, LEDs, Micro LEDs), other corresponding structures of the display panel may be formed on the array substrate. That is, the disclosure further provides an application of the above-mentioned array substrate of a display panel, such as, but not limited to an OLED, a QLED, an LED, and a Micro LED.

The disclosure also provides a display device comprising the above-mentioned array substrate or comprising a display panel as described above.

The disclosure further provides an electronic device comprising an array substrate as described above, or comprising a display panel as described above. The electronic device is a terminal device comprising a display panel, such as, but not limited to, a mobile phone, a smart phone, a notebook, a digital broadcast receiver, a PDA (personal digital assistant), a PAD (tablet computer), a PMP (portable multimedia player) Device), and a navigation device, etc.

In the disclosure, the term “first region” is defined as a region in which the inorganic insulating layer is required for insulating, and the term “second region” is defined as a region in which the inorganic insulating layer may not be required.

For example, when the array substrate of the disclosure comprises at least the following structure: an active layer, a first gate insulating layer, a first gate, an interlayer insulating layer, an organic dielectric layer, and a source/drain sequentially formed on the flexible substrate, the first region is a region covered by the first gate insulating layer and only the region of the active layer is covered. The first region is a region covered by the interlayer insulating layer and only the region of the first gate (also including a gate line and a gate pad portion of the non-display area formed together with the first gate) is covered. When the array substrate of the disclosure comprises a double gate structure, that is, when the array substrate comprises at least the following structure: an active layer, a first gate insulating layer, a first gate, a second gate insulating layer, a second a gate, an interlayer insulating layer, an organic dielectric layer, and a source/drain sequentially formed on the flexible substrate, the first region is a region covered by the first gate insulating layer and only the region of the active layer is covered. The first region is a region covered by the second gate insulating layer and only the region of the first gate (also including a gate line and a gate pad portion of the non-display area formed together with the first gate) is covered. The first region is a region covered by the interlayer insulating layer and only the region of the second gate (also including a gate line and a gate pad portion of the non-display area formed together with the second gate) is covered. The second region is an entire region except the first region in the first gate insulating layer, the second gate insulating layer, and the interlayer insulating layer.

Of course, the inorganic insulating layer further includes a buffer layer formed between the active layer and the flexible substrate. The buffer layer is also located in the first region. That is, the buffer layer is only disposed between the active layer and the flexible substrate.

The disclosure further provides an array substrate comprising a flexible substrate. The flexible substrate comprising a curved portion and a functional portion, and at least one patterned functional layer. The patterned functional layer is disposed on the flexible substrate, and the flexible substrate further comprises an inorganic insulating layer disposed on the patterned functional layer. A pattern of the inorganic insulating layer corresponds to a pattern of the patterned functional layer.

It should be noted that a description “a pattern of the inorganic insulating layer corresponds to a pattern of the patterned functional layer” means that the inorganic insulating layer only covers the patterned functional layer, that is, the pattern of the insulating layer is identical to the pattern of the patterned functional layer and completely overlaps spatially. Of course, engineering errors are unavoidable.

In an embodiment of the disclosure, the patterned functional layer is an active layer, a first patterned metal layer or a second patterned metal layer. It can be understood by those skilled in the art that the first patterned metal layer includes a plurality of first gates located in a display area of the display panel, a plurality of gate pads located in a non-display area of the display panel, and gate lines connecting the first gates and the gate pads. Similarly, the second patterned metal layer includes a plurality of second gates located in the display area of the display panel, a plurality of gate pads located in the non-display area of the display panel, and gate lines connecting the second gates and the gate pads.

In an embodiment of the disclosure, the array substrate further comprises an organic dielectric layer disposed on the inorganic insulating layer and completely covering the flexible substrate. The organic dielectric layer forms a groove at a boundary of the curved portion and the functional portion. The groove penetrates through the organic dielectric layer to expose the flexible substrate.

In an embodiment of the disclosure, the array substrate further comprises a third patterned metal layer, and the third patterned metal layer comprises a plurality of sources and a plurality of drains. It can be understood by those skilled in the art that the third patterned metal layer comprises a plurality of sources and a plurality of drains located in the display area of the display panel, and scan lines and other wires located in the non-display area.

In an embodiment of the disclosure, the array substrate further comprises a buffer layer disposed on the flexible substrate and in contact with the flexible substrate. A pattern of the buffer layer corresponds to a pattern of the functional layer.

That is, in the array substrate described above, the inorganic insulating layer is only formed on the active layer, the first gate (and/or the second gate) and wires thereof, the source/drain and wires thereof for insulation.

The disclosure further provides a method of manufacturing the array substrate described above. The method comprises steps of: a step S1 of providing a flexible substrate, the flexible substrate comprising a curved portion and a functional portion; a step S2 of forming a patterned functional layer on the flexible substrate; and a step S3 of forming an inorganic insulating layer on the patterned functional layer, patterning the inorganic insulating layer such that a pattern of the inorganic insulating layer corresponds to a pattern of the patterned functional layer and removing a remaining portion of the inorganic insulating layer.

The method further comprises a step S4 of forming a comprehensively covered organic dielectric layer such that the organic dielectric layer is disposed on the inorganic insulating layer and contacts with the flexible substrate; and patterning the organic dielectric layer to form a groove at a boundary of the curved portion and the functional portion. The groove penetrates through the organic dielectric layer to expose the flexible substrate.

The method further comprises a step S5 of forming a third patterned metal layer on the organic dielectric layer. The third patterned metal layer comprises a plurality of sources and a plurality of drains.

The method further comprises a step of, which is between the step S1 and the step S2, forming a buffer layer on the flexible substrate and patterning the buffer layer to make a pattern of the buffer layer corresponds to a pattern of the patterned functional layer.

In an embodiment of the disclosure, the flexible substrate is made of polyimide.

In the disclosure, it can be understood by those skilled in the art that layers are formed by a conventional method. For example, in an embodiment of the disclosure, a method of forming the active layer on the buffer layer comprises depositing an amorphous silicon layer on the buffer layer and performing a molecular laser annealing process to the amorphous silicon layer so that the amorphous silicon layer is crystallized and converted into a polysilicon layer. The polysilicon layer is patterned by a yellowing process or an etching process to form a polysilicon segment, and then a source contact region and a drain contact region are formed at both ends of the polysilicon segment by a deposition, yellowing, or etching process. Materials forming the first gate and the second gate are conventional metal materials that form a gate in the art. A material forming the inorganic insulating layer is a conventional inorganic material that forms a gate insulating layer (or barrier gate) in the art, such as a metal oxide (such as silicon oxide, aluminum oxide, tin oxide, zinc oxide, indium tin oxide), indium zinc oxide, aluminum oxide zinc, etc), metal nitrides (such as silicon nitride, aluminum nitride, boron nitride), metal oxynitrides (such as aluminum oxynitride, silicon oxynitride, boron oxynitride), metal carbonization (such as tungsten carbide, boron carbide, silicon carbide), metal boron oxide (such as zirconium oxyborate, titanium oxynitride, etc) and combinations thereof.

In the disclosure, forming a first contact hole and a second contact hole with a photomasks omits the number of photomasks in the process and simplifies the process. In addition, in the disclosure, a configuration of the inorganic insulating layers of the buffer layer, the first gate insulating layer, the second gate insulating layer, and the interlayer insulating layer for insulating is adjusted. Only portions of the inorganic insulating layers that functions as an insulating layer are retained, and remaining portions are entirely etched. All unnecessary portions (i.e., the unnecessary portions are portions that do not contact the active layer, the patterned first metal layer, etc., which do not function as an insulating layer) of the inorganic insulating layer (including the buffer layer, the first gate insulating layer, the second gate insulating layer, and the interlayer insulating layer) in the display area and the non-display area of the flexible substrate are removed, thereby minimizing the inorganic insulating layer in the curved portion (display area) of the display panel. Inorganic materials are effectively prevented from breaking when the display panel is folded. Moreover, in the disclosure, a groove is formed at a boundary between the display area and the non-display area of the flexible substrate on the organic dielectric layer, the planarization layer, and the pixel defining layer to expose the flexible substrate, thereby preventing device failure caused by organic matters entering into the display area with moisture.

### DESCRIPTION OF DRAWINGS

FIG. 1 is a structural schematic view of a display panel of the disclosure.

FIG. 2 is a schematic view of step S1 of a method of manufacturing the display panel of this disclosure.

FIG. 3 is a schematic view of step S2 of the method of manufacturing the display panel of this disclosure.

FIG. 4A and FIG. 4B are schematic views of step S3 of the method of manufacturing the display panel of this disclosure.

FIG. 5 is a schematic view of step S4 of the method of manufacturing the display panel of this disclosure.

FIG. 6 is a schematic view of step S5 of the method of manufacturing the display panel of this disclosure.

FIG. 7 is a schematic view of step S7 of the method of manufacturing the display panel of this disclosure.

FIG. 8 is a schematic view of step S8 of the method of manufacturing the display panel of this disclosure.

FIG. 9 is a schematic view of step S9 of the method of manufacturing the display panel of this disclosure.

FIG. 10 is a schematic view of step S10 of the method of manufacturing the display panel of this disclosure.

### DETAILED DESCRIPTION OF PREFERRED EMBODIMENTS

The specific details disclosed herein are merely representative and are intended to describe the purpose of the exemplary embodiments of this disclosure. This disclosure may be embodied in many and may not be construed as limited to the embodiments set forth herein.

This description of the exemplary embodiments is intended to be read in connection with the accompanying drawings, which are to be considered part of the entire written description. In the description, terms such as “lower”, “upper”, “horizontal”, “vertical”, “above”, “below”, “up”, “down”, “top”, and “bottom”, as well as derivatives thereof, should be construed to refer to the orientation as then described or as shown in the drawing under discussion. These terms are for convenience of description and do not require that the apparatus be constructed or operated in a particular orientation, and do not limit the scope of the disclosure. Referring to the drawings of the disclosure, similar components are labeled with the same number.

The following description provides many different embodiments or examples for implementing different structures of the disclosure. In order to simplify the disclosure, components and arrangements of specific examples are described below. Of course, they are merely examples and are not intended to limit the disclosure. In addition, in the disclosure, reference numbers and/or reference numerals in different examples can be repeated in the various examples, which are for the purpose of simplicity and clarity, and do not indicate the relationship between the various embodiments and/or arrangements discussed. Moreover, the disclosure provides examples of various specific processes and materials, but one of ordinary skill in the art will recognize the use of other processes and/or the use of other materials.

In the disclosure, this disclosure provides a display panel. The display panel comprises an array substrate described above. In the disclosure, OLED display panel is taken as an example for detailed description. Certainly, it should be understood by those skilled in the art that the array substrate described in the disclosure is applied to other types display panels, such as, but not limited to an OLED, a QLED, an LED, and a micro LED. When the array substrate described in the disclosure is applied to other types display panels, other corresponding structures of the display panel may be formed on the array substrate.

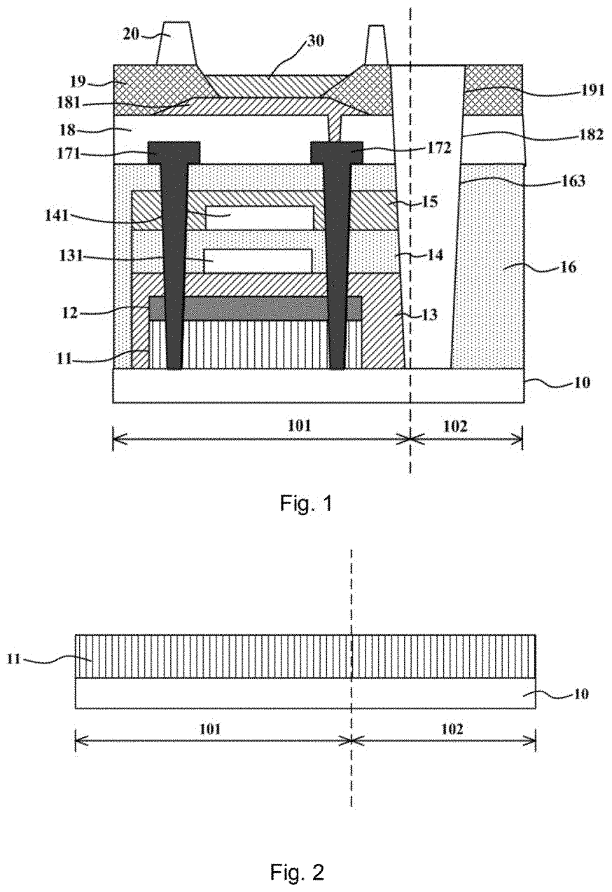

A structure of the display panel is shown in FIG. 1. As shown in FIG. 1, the display panel comprises a flexible substrate 10. The flexible substrate 10 comprises a display area 101 and a non-display area 102. As shown in FIG. 1, the display panel comprises a buffer layer 11 disposed in the display area 101 of the flexible substrate, an active layer 12 disposed on the buffer layer 11, a first gate insulating layer 13 and a first gate 131 disposed on the first gate insulating layer, a second gate insulating layer 14 and a second gate 141 disposed on the second gate insulating layer 14, an interlayer insulating layer 15 disposed on the second gate 141, an organic dielectric layer 16 disposed on the interlayer insulating layer 15, a source 171 and a drain 172 disposed on the organic dielectric layer 16, a flat layer overlapping the source 171 and the drain 172, an anode 181 disposed on the flat layer 18, a pixel defining layer 19 disposed on the anode 18, a spacer 20 formed on the pixel defining layer 19, and a light emitting layer 30 disposed on the anode 181 required for an OLED device.

The spacer 20 is used to provide a thickness of the OLED display panel. The flexible substrate 10 is made of polyimide (PI).

As shown in FIG. 1, in the embodiment of the display panel, all portions, which do not have an insulating function (i.e., the second region), of the inorganic insulating layer (including the buffer layer 11, the first gate insulating layer 13, the second gate insulating layer 14, and the interlayer insulating layer 15) in the flexible substrate 10 are removed, and only portions that functions as an insulating layer (i.e., the first region) is retained, thereby effectively preventing inorganic materials from being broken when the display panel is folded. That is, in this embodiment, in the display area shown in FIG. 1, only the inorganic insulating layer (the first gate insulating layer 13, the second gate insulating layer 14, and the interlayer insulating layer 15) in the first region, which has the insulating function, corresponding to the active layer, the first gate, and the second gate is retained, and the remaining inorganic insulating layers (i.e., the second region) are all removed.

A method of manufacturing the display panel will be described in detail below with reference to FIGS. 2-10.

The method of manufacturing the display panel of this embodiment specifically includes following steps.

In a step S1, providing a flexible substrate, as shown in FIG. 2. The flexible substrate 10 comprises a display area 101 and a non-display area 102. A buffer layer 11 is formed on the flexible substrate 10. The buffer layer 11 can be formed in a conventional method, for example, by a chemical vapor deposition. Also, a composition of the buffer layer 11 is a conventional component.

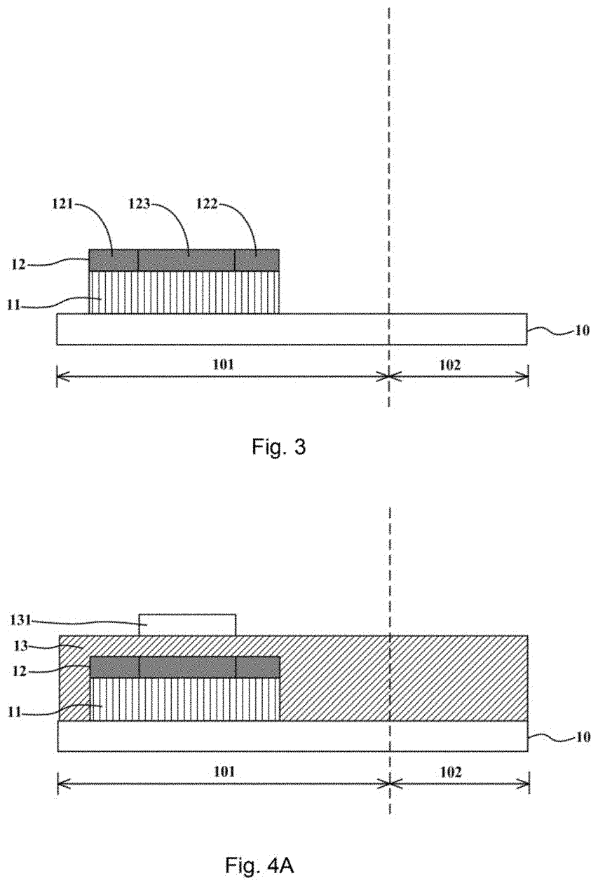

In a step S2, forming a polysilicon layer (not shown) on the buffer layer, and patterning the polysilicon layer and the buffer layer 11 to obtain an active layer 12 as shown in FIG. 3 and retaining only a portion of the buffer layer 11 corresponding to the active layer 12. As shown in FIG. 3, a remaining portion of the buffer layer 11 is removed, so that the flexible substrate 10 is entirely exposed except the active layer 11. As shown in FIG. 3, the active layer 12 comprises a source contact region 121, a drain contact region 122, and a channel region 123 between the source contact region 121 and the drain contact region 122. It can be understood by those skilled in the art that forming the active layer 12 on the buffer layer 11 is to deposit an amorphous silicon layer on the buffer layer 11 and subject the amorphous silicon layer to perform a molecular laser annealing process so that the amorphous silicon layer is crystallized and converted into a polysilicon layer. The polysilicon layer is patterned by a yellowing process or an etching process to form a polysilicon segment, and then a source contact region 121 and a drain contact region 122 are formed at both ends of the polysilicon segment by a deposition, yellowing, or etching process.

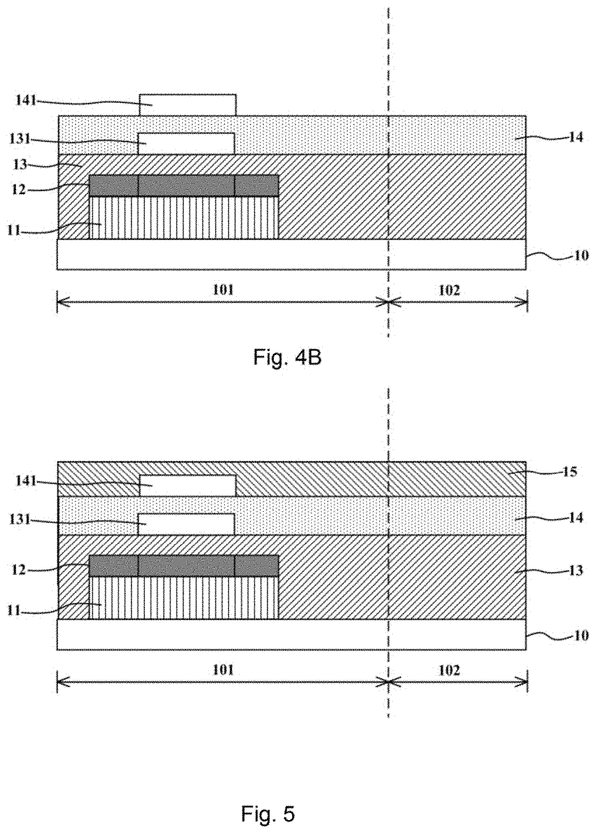

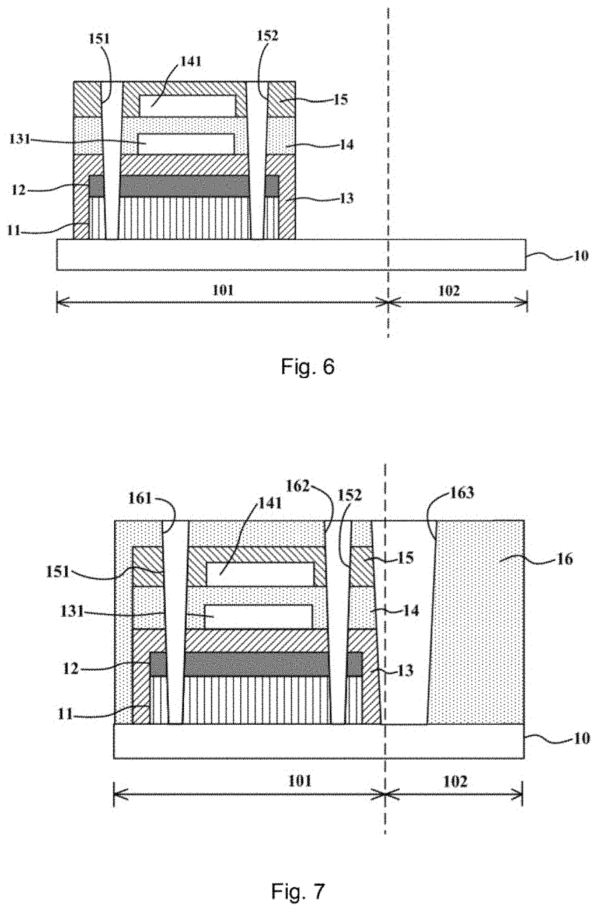

In a step S3, as shown in FIG. 4A, firstly, forming the first gate insulating layer 13 on the active layer 12 and forming the first gate 131 on the first gate insulating layer 13. Secondly, as shown in FIG. 4B, the second gate insulating layer 14 is formed on the first gate 131 and the second gate 141 is formed on the second gate insulating layer 14. As shown in FIGS. 4A and 6B, the first gate insulating layer 13 covers the active layer 12 and the flexible substrate 10, and the first gate 131 is located above the active layer 12. The second gate insulating layer 14 covers the first gate 131 and the first gate insulating layer 13, and the second gate 141 is located above the first gate 131.

In a step S4, forming an interlayer insulating layer 15 on the second gate 141. As shown in FIG. 5, the interlayer insulating layer 15 covers the second gate 141 and the second gate insulating layer 14. The interlayer insulating layer 15 is formed in a conventional method, for example, by a chemical vapor deposition method. Also, a composition of the interlayer insulating layer 15 is a conventional component.

In a step S5, etching the interlayer insulating layer 15, the second gate insulating layer 14, and the first insulating layer 13 with a photomask to form a first contact hole 151 and a second contact hole 152 as shown in FIG. 6. Additionally, as shown in FIG. 6, in this step, “a region in which an insulating layer is required to be insulated” is defined as a first region, and “a region in which an inorganic insulating layer may not be required” is defined. A division of the first region and the second region is performed in a plan view, for example, from a frontal perspective view. As shown in FIG. 6, the first region comprises a portion that just cover where the active layer 12, the first gate 131, the first gate insulating layer 13 of the second gate 141, the gate insulating layer 14, and the interlayer insulating layer 15 are located in FIG. 6. The second region comprises other portions on the left and right sides of the portion. The interlayer insulating layer 15, the first gate insulating layer 13, and the second gate insulating layer 14 are etched by one photomask to retain the first region as shown in FIG. 6.

It can be understood by those skilled in the art that widths of the first gate insulating layer 13, the second gate insulating layer 14 and the interlayer insulating layer 15 in FIG. 6 are consistent and slightly wider than a width of active layer 12. This is due to the etching is performed by the same photomask. This design does not affect technical effects described herein. However, it can be understood by those skilled in the art that the first gate insulating layer 13, the second gate insulating layer 14 and the interlayer insulating layer 15 can also be etched by multiple photomasks respectively, so that the first gate insulating layer 13 only covers the active layer 12, and the second gate insulating layer 14 only covers the first gate 131 (surely, also includes gate lines and pads formed together with the first gate 131), and the interlayer insulating layer only covers the second gate 141 (surely, also includes gate lines and pads formed together with the second gate 141).

As shown in FIG. 6, the first contact hole 151 penetrates through the interlayer insulating layer 15, the second gate insulating layer 14, the first gate insulating layer 13, the source contact region of the active layer 12, and the buffer layer 11 to expose the flexible substrate 10. The second contact hole 152 penetrates through the interlayer insulating layer 15, the second gate insulating layer 14, the first gate insulating layer 13, the drain contact region of the active layer 12, and the buffer layer 11 to expose the flexible substrate 10.

In a step S6, forming an organic dielectric layer 16 on the interlayer insulating layer 15 so that the organic dielectric layer 16 covers the interlayer insulating layer 15 and the non-display area 102 of the flexible substrate 10. The organic dielectric layer 16 is formed by a conventional method, for example, by a chemical vapor deposition method.

In a step S7, etching the organic dielectric layer 16 with a photomask to form a third contact hole 161, a fourth contact hole 162, and a first groove 163 as shown in FIG. 7. As shown in FIG. 7, the third contact hole 161 corresponds to the first contact hole 151, the fourth contact hole 162 corresponds to the second contact hole 152, and the first groove 163 is disposed at a boundary between the display area 101 and the non-display area 102 of the flexible substrate 10 to expose the flexible substrate 10. Since the organic dielectric layer 16 is made of an organic material, an impermeability of the organic material is inferior to that of an inorganic material, and moisture easily permeates into the display panel through the organic dielectric 16, thereby causing failure of a device for driving TFT. The groove 163 located at the boundary between the display area and the non-display area of the flexible substrate 10 can prevent device failure caused by organic matters permeating into the display area with moisture.

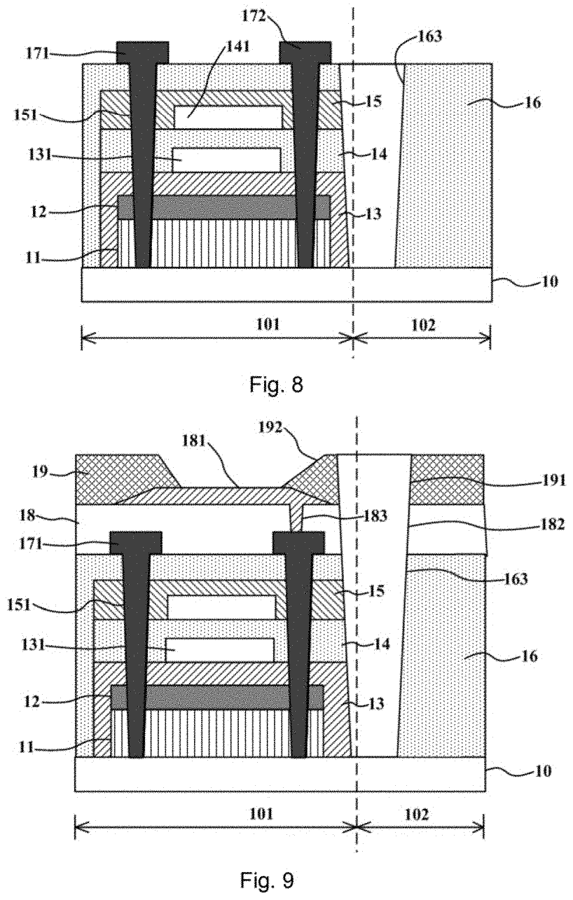

In a step S8, forming a source 171 and a drain 172 on the organic dielectric layer 16. A method of forming the source 171 and the drain 172 comprises depositing a metal layer for forming the source 171 and the drain 172 on the organic dielectric layer 16 by a physical vapor deposition method. Then, a patterning process is performed to the metal layer to obtain the source 171 and the drain 172 as shown in FIG. 8. As shown in FIG. 7 and FIG. 8, the source 171 is in contact with the flexible substrate 10 through the third contact hole 161 and the first contact hole 151 shown in FIG. 7, and the drain 172 is in contact with the flexible substrate 10 through the fourth contact hole 162 and the second contact hole 152, as shown in FIG. 7

In a step S9, forming a flat layer 18 on the source 171 and the drain 172, forming an anode 181 on the flat layer 18 and forming a pixel defining layer 19 on the anode 181. As shown in FIG. 8 and FIG. 9, the flat layer 18 forms a second groove 182 at a position corresponding to the first groove 163, and the pixel defining layer 19 forms a third groove 191 at a position of the second groove 181 to expose the flexible substrate 10.

A through hole 183 is formed on the flat layer 18, and the through hole 183 corresponds to the drain 172 shown in FIG. 8 such that the anode 181 is in contact with the drain 172 through the through hole 183. Also, as shown in FIG. 9, a blank region 192 is formed on the pixel defining layer 19 at a position corresponding to the anode 181 to expose the anode 181.

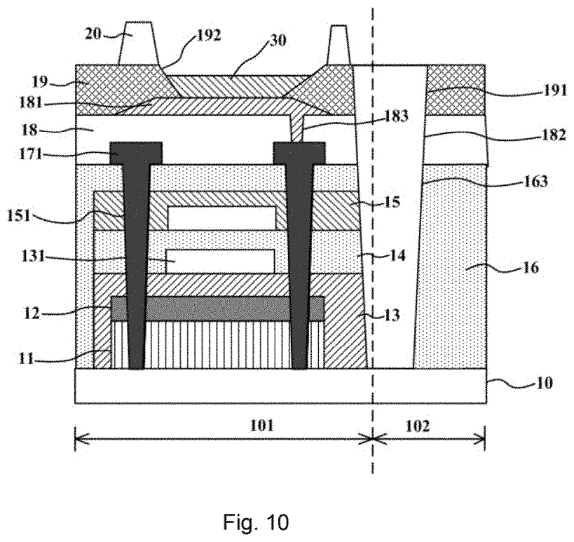

In a step S10, as shown in FIG. 10, at least one spacer 20 is further formed on the pixel defining layer 19, and the spacer 20 is used to provide a thickness of the OLED display panel. Of course, there is also a luminescent layer 30 required for the OLED device on the anode 181.

This disclosure further provides a display panel. The display panel comprises a first region and a second region. The display panel comprises a flexible substrate, a first layer disposed on the flexible substrate and located on the first region, a second layer disposed on the flexible substrate and located on the first region, and an inorganic insulating layer disposed between the first layer and the second layer. The inorganic insulating layer is located on the first region and is not located on the second region. In this embodiment, the first region and the second region are disposed not only on the array substrate but also in other structures of the display panel. This can improve flexibility of the display panel.

The disclosure further provides a display device comprising the array substrate mentioned above, or an OLED, QLED, LED, Micro LED display panel made of the array substrate mentioned above.

The disclosure further provides an electronic device comprising an array substrate as described above, or comprising a display panel as described above. The electronic device is a terminal device comprising a display panel, such as, but not limited to, a mobile phone, a smart phone, a notebook, a digital broadcast receiver, a PDA (personal digital assistant), a PAD (tablet computer), a PMP (portable multimedia player) Device), and a navigation device, etc.

In the disclosure, forming a first contact hole and a second contact hole with a photomasks omits the number of photomasks in the process and simplifies the process. In addition, in the disclosure, a configuration of the inorganic insulating layers of the buffer layer, the first gate insulating layer, the second gate insulating layer, and the interlayer insulating layer for insulating is adjusted. Only portions of the inorganic insulating layers that functions as an insulating layer are retained, and remaining portions are entirely etched. All unnecessary portions (i.e., the unnecessary portions are portions that do not contact the active layer, the patterned first metal layer, etc., which do not function as an insulating layer) of the inorganic insulating layer (including the buffer layer, the first gate insulating layer, the second gate insulating layer, and the interlayer insulating layer) in the display area and the non-display area of the flexible substrate are removed, thereby minimizing the inorganic insulating layer in the curved portion (display area) of the display panel. Inorganic materials are effectively prevented from breaking when the display panel is folded. Moreover, in the disclosure, a groove is formed at a boundary between the display area and the non-display area of the flexible substrate on the organic dielectric layer, the planarization layer, and the pixel defining layer to expose the flexible substrate, thereby preventing device failure caused by organic matters entering into the display area with moisture.

This disclosure has been described with preferred embodiments thereof, and it is understood that many changes and modifications to the described embodiment can be carried out without departing from the scope and the spirit of the disclosure that is intended to be limited only by the appended claims.

1. An array substrate, comprising a first region and a second region, the array substrate, comprising:
a flexible substrate;
a first layer disposed on the flexible substrate and located on the first region;
a second layer disposed on the flexible substrate and located on the first region; and
an inorganic insulating layer disposed between the first layer and the second layer and located on the first region and not located on the second region;
wherein one of the first layer and the second layer is a metal layer;
wherein the first layer comprises an active layer;
wherein the second layer comprises a first gate; and
wherein the inorganic insulating layer comprises a first gate insulating layer disposed on the active layer and the first gate.

2. The array substrate according to claim 1, wherein the first layer further comprises a second gate, and the inorganic insulating layer further comprises a second gate insulating layer disposed between the first gate and the second gate.

3. The array substrate according to claim 2, wherein the array substrate further comprises an organic dielectric layer, the organic dielectric layer comprises a first portion disposed on the second region and a second portion disposed on the inorganic insulating layer.

4. The array substrate according to claim 3, wherein the second layer further comprises a source/drain, the source/drain extends through the first gate insulating layer and the second gate insulating layer and connects with the active layer;
wherein the inorganic insulating layer further comprises an interlayer insulating layer disposed between the second gate and the source/drain, the second portion of the organic dielectric layer is disposed between the source/drain and the interlayer insulating layer.

5. The array substrate according to claim 4, wherein the second region comprises a curved portion corresponding to a non-display area of a display panel, and the first region comprises a functional portion corresponding to a display area of the display panel and adjacent to the curved portion, the array substrate is provided with a groove adjacent to an interface between the curved portion and the display portion, and the groove penetrates through the organic dielectric layer to expose the first gate insulating layer, the second gate insulating layer and the interlayer insulating layer.

6. The array substrate according to claim 5, wherein the array substrate further comprises a buffer layer between the flexible substrate and the active layer, and the source/drain extends through the active layer and the buffer layer.

7. The array substrate according to claim 1, wherein the array substrate comprises a functional region corresponding to the display area of the display panel, and the functional region comprises the first region and the second region.

8. An array substrate, comprising a first region and a second region, the array substrate further comprising:
a flexible substrate;
a first layer disposed on the flexible substrate and located on the first region;
a second layer disposed on the flexible substrate and located on the first region; and
an inorganic insulating layer disposed between the first layer and the second layer, wherein the inorganic insulating layer is located on the first region and is not located on the second region.

9. The array substrate according to claim 8, wherein the array substrate further comprises an organic dielectric layer, the organic dielectric layer comprises a first portion disposed on the second region.

10. The array substrate according to claim 9, wherein the organic dielectric layer further comprises a second portion disposed on the inorganic insulating layer.

11. The array substrate according to claim 10, wherein one of the first layer and the second layer is a metal layer.

12. The array substrate according to claim 10, wherein the first layer comprises an active layer, the second layer comprises a first gate, and the inorganic insulating layer comprises a first gate insulating layer disposed on the active layer and the first gate.

13. The array substrate according to claim 12, wherein the first layer further comprises a second gate, and the inorganic insulating layer further comprises a second gate insulating layer disposed between the first gate and the second gate.

14. The array substrate according to claim 13, wherein the second layer further comprises a source/drain, the source/drain extends through the first gate insulating layer and the second gate insulating layer and connects with to the active layer, and wherein the inorganic insulating layer further comprises an interlayer insulating layer disposed between the second gate and the source/drain, the second portion of the organic dielectric layer is disposed between the source/drain and the interlayer insulating layer.

15. The array substrate according to claim 14, wherein the second region comprises a curved portion corresponding to a non-display area of a display panel, and the first region comprises a functional portion corresponding to a display area of the display panel and adjacent to the curved portion, the array substrate is provided with a groove adjacent to an interface between the curved portion and the display portion, and the groove penetrates through the organic dielectric layer to expose the first gate insulating layer, the second gate insulating layer and the interlayer insulating layer.

16. The array substrate according to claim 14, wherein the array substrate further comprises a buffer layer between the flexible substrate and the active layer, and the source/drain extends through the active layer and the buffer layer.

17. The array substrate according to claim 8, wherein the array substrate comprises a functional region corresponding to the display area of the display panel, and the functional region comprising the first region and the second region.

18. A display panel, comprising a first region and a second region, the display panel comprising:
a flexible substrate;
a first layer disposed on the flexible substrate, wherein the first layer is located on the first region;
a second layer disposed on the flexible substrate, wherein the second layer is located on the first region; and
an inorganic insulating layer disposed between the first layer and the second layer, wherein the inorganic insulating layer is located on the first region and is not located on the second region;
wherein one of the first layer and the second layer is a metal layer;
wherein the first layer comprises an active layer;
wherein the second layer comprises a first gate; and
wherein the inorganic insulating layer comprises a first gate insulating layer disposed on the active layer and the first gate.

19. The display panel according to claim 18, wherein the first layer further comprises a second gate, and the inorganic insulating layer further comprises a second gate insulating layer disposed between the first gate and the second gate.

20. The display panel according to claim 19, wherein the array substrate further comprises an organic dielectric layer, the organic dielectric layer comprises a first portion disposed on the second region and a second portion disposed on the inorganic insulating layer.
